(19) United States
(12) Patent Application Publication
(10) Pub. No.: US 2016/0010488 A1
(43) Pub. Date: Jan. 14, 2016

(54) WEAR PROTECTION ARRANGEMENT FOR A TURBOMACHINE, PROCESS AND COMPRESSOR

(71) Applicant: MTU Aero Engines AG, Munich (DE)

(72) Inventors: Lothar ALBERS, Munich (DE); Stephan BOCK, Olching (DE); Stefan SCHNEIDERBANGER, Dachau (DE)

(21) Appl. No.: 14/792,941

(22) Filed: Jul. 7, 2015

(30) Foreign Application Priority Data
Jul. 8, 2014 (DE) 102014213263.0

(51) Int. Cl. F01D 17/16; F01D 25/00; C23C 14/06; C23C 4/06; C23C 16/36; F01D 9/04; F01D 25/24

(52) U.S. Cl. CPC F01D 17/16; F01D 9/041; F01D 25/005; F01D 25/24; C23C 4/06; C23C 16/36; C23C 14/0664; F05D 2220/30; F05D 2230/90; F05D 2240/12; F05D 2300/173; F05D 2300/177; F05D 2300/132; F05D 2300/121

(57) ABSTRACT

The present invention relates to a wear protection arrangement for a turbomachine, comprising at least one adjustable guide vane, a casing in which the guide vane is arranged in an adjustable manner, an inner ring, made from a metallic material, in or on which the guide vane is arranged in an adjustable manner, a first gap between an inner guide vane tab and the inner ring and a second gap between an outer guide vane tab and the casing, at least one wear protection coating, wherein the wear protection coating(s) is/are connected to the inner ring and/or to the inner guide vane tab and the wear protection coating(s) forms or form the first gap, at least in certain regions, and/or the wear protection coating(s) is/are connected to the casing and/or to the outer guide vane tab and the wear protection coating(s) forms/form the second gap, at least in certain regions. The invention further relates to a method for applying an abradable wear protection coating and for applying an abrasive wear protection coating and to a compressor for a turbomachine having a wear protection arrangement.

### CROSS-REFERENCE TO RELATED APPLICATIONS

The present application claims priority under 35 U.S.C. §119 of German Patent Application No. 102014213263.0, filed Jul. 8, 2014, the entire disclosure of which is expressly incorporated by reference herein.

### BACKGROUND OF THE INVENTION

1. Field of the Invention

The present invention relates to a wear protection arrangement for a turbomachine. Furthermore, the present invention relates to a method for applying an abradable wear protection coating to an inner ring and/or a casing of a wear protection arrangement, a method for applying an abrasive wear protection coating to an inner and/or to an outer guide vane tab of a wear protection arrangement and to a compressor for a turbomachine having at least one wear protection arrangement.

2. Discussion of Background Information

In turbomachines, adjustable guide vanes can be used for controlling the volume flow rate. The guide vanes are generally mounted adjustably in the casing of the turbomachine and in inner rings of the stators. With a view to optimizing efficiency, the gaps between the guide vane tabs, that is to say the radially inner and outer vane ends, and the casing or the inner ring should be kept small. However, in the case of small gaps and possible large adjustment angles of the guide vanes, there exists the risk of contact or rubbing between the vane tabs and the surfaces of the casing or of the inner ring. However, contact between the vane tabs and the surfaces of the casing or of the inner ring can also be caused by wear of the guide vane mounting in the casing and/or in the inner ring. Furthermore, what are referred to as ovalities can lead to such contact or abrasive contact, hereinbelow termed damage for short. Ovalities can be caused by out-of-roundnesses of the guide vane mountings in the casing or in the inner ring, for example as a consequence of manufacturing. Ovalities on inner rings and/or on casings can however also for example be caused by thermal effects or pressure forces. This damage can lead to these components having to be repaired or exchanged, which in turn can mean longer downtimes and high repair costs.

It would therefore be desirable to provide an arrangement for turbomachines which avoids longer downtimes and high repair costs in the event of damage of the above-described type. It would further be desirable to provide a method for applying an abradable wear protection coating and a method for applying an abrasive wear protection coating. It would further be desirable to provide a compressor for a turbomachine.

### SUMMARY OF THE INVENTION

The present invention provides a wear protection arrangement for a turbomachine, as indicated in the appended claims. The invention further provides a method for applying an abradable wear protection coating to an inner ring and/or a casing of a wear protection arrangement, a method for applying an abrasive wear protection coating to an inner and/or to an outer guide vane tab of a wear protection arrangement and a compressor for a turbomachine having at least one wear protection arrangement, also as in each case indicated in the appended claims.

The invention thus proposes a wear protection arrangement for a turbomachine having at least one adjustable guide vane. The wear protection arrangement comprises a casing in which the at least one guide vane is arranged in an adjustable manner. The wear protection arrangement further comprises an inner ring made from a metallic material.

The wear protection arrangement according to the invention further comprises a first gap between an inner guide vane tab and the inner ring and a second gap between an outer guide vane tab and the casing.

The wear protection arrangement according to the invention also comprises at least one wear protection coating. The at least one wear protection coating is connected to the inner ring or to the inner guide vane tab. Alternatively, at least one wear protection coating is connected to the inner ring and at least one further wear protection coating is connected to the inner guide vane tab. The one or more wear protection coating(s) forms or form the first gap, at least in certain regions.

In addition or as an alternative, the wear protection arrangement according to the invention comprises at least one wear protection coating which is connected to the casing or to the outer guide vane tab. Alternatively, at least one wear protection coating is connected to the casing and at least one further wear protection coating is connected to the outer guide vane tab. The one or more wear protection coating(s) forms or form the second gap, at least in certain regions.

The method according to the invention for applying an abradable wear protection coating to an inner ring and/or a casing of a wear protection arrangement comprises the step of applying the abradable wear protection coating by means of a thermal spraying method.

The method according to the invention for applying an abrasive wear protection coating to an inner and/or to an outer guide vane tab of a wear protection arrangement comprises one of the three following steps. The abrasive wear protection coating is applied either by means of a thermal spraying method, or by means of a physical vapor deposition (PVD) method, or by means of a chemical vapor deposition (CVD) method.

The compressor according to the invention for a turbomachine comprises at least one wear protection arrangement according to the invention.

In all of the explanations above and below, use of the expression “may be” or “may have” and so on is to be understood as respectively synonymous with “is preferably” and “preferably has” etc. and is intended to illustrate embodiments according to the invention.

Whenever numerical words are mentioned herein, a person skilled in the art will understand these as an indication of a numerically lower limit. As long as this leads to no contradiction which is apparent to the person skilled in the art, the person skilled in the art will therefore for example always understand the indication “one” as meaning “at least one”. This understanding is also encompassed by the present invention alongside the interpretation that a numerical word such as “one” may alternatively be intended to mean “exactly one”, wherever the person skilled in the art recognizes this as technically feasible. Both are encompassed by the present invention and are valid for all the numerical words used herein.

Advantageous developments of the present invention are respectively the subject matter of subclaims and embodiments.

Exemplary embodiments according to the invention may have one or more of the features mentioned below.

In the following, gas turbines are in particular described, purely as examples of turbomachines, with no intention of restricting turbomachines to gas turbines. The turbomachine can in particular be an axial-flow turbomachine. The gas turbine may in particular be an axial-flow gas turbine, for example an aero gas turbine.

The term “adjustment range” of the guide vane, as is used herein, relates to a range which comprises a guide vane section and a casing section and/or an inner ring section and within which the guide vane is arranged in an adjustable or rotatable manner. The adjustment range of the guide vane in the region of the casing thus comprises both the casing section and the guide vane section (in particular the guide vane tab) which covers or shields this range. The guide vane tab can be separated from the casing section by a gap or be in contact with the casing section. The adjustment range of the guide vane in the region of the inner ring is to be understood similarly.

In some embodiments according to the invention, the at least one wear protection coating is separably connected to the inner ring or to the inner guide vane tab. Alternatively, the at least one wear protection coating can be separably connected to the inner ring and at least one further wear protection coating can be separably connected to the inner guide vane tab.

In some embodiments according to the invention, the wear protection arrangement according to the invention comprises, in addition or as an alternative, at least one wear protection coating which is separably connected to the casing or to the outer guide vane tab. Alternatively, at least one wear protection coating can be separably connected to the casing and at least one further wear protection coating can be separably connected to the outer guide vane tab.

A separable connection between the wear protection coating and a base material is for example a connection which allows the wear protection coating to be exchanged or replaced for example if it is damaged or worn. A separable connection can be an adhesively bonded connection which can be undone by means of heat or by means of solvent and can then be applied anew. Equally, a separable connection can be a form-fitting connection which can additionally be mechanically fixed.

In certain embodiments according to the invention, a separable wear protection coating is entirely or partially destroyed during the separation procedure. For example, a sprayed-on wear protection coating, which can be termed as spray cladding, can be separated or removed mechanically and/or chemically. Mechanical separation can for example be achieved by removal by turning or by milling. Chemical separation can be achieved by chemically releasing or dissolving the wear protection coating.

The guide vane can be turned in the adjustment range, and is in particular arranged such that it can be turned through a predefined angular range. The guide vane is in particular arranged such that it can be turned along its longitudinal axis. The longitudinal axis can run through the two mounting pegs at the ends of the guide vane.

In certain embodiments according to the invention, the wear protection coating is a cladding.

In certain embodiments according to the invention, the wear protection coating is provided for protecting a base material which can be arranged beneath the protection coating. The base material can for example be or have the material of the casing of the turbomachine, of the inner ring of the guide vane or of the guide vane. The wear protection coating can be provided to prevent damage to a component which has been manufactured from the base material.

In some exemplary embodiments according to the invention, the wear protection coating is separably connected to a base material, for example of the inner ring or of the casing. As a consequence of operation-induced wear, temporary overload or other procedures, it can be necessary to repair the wear protection coating. The wear protection arrangement according to the invention makes it possible to remove the wear protection coating by separating it from the base material. It is then possible to re-coat with a new wear protection coating. The original geometric state of the arrangement in the turbomachine, for example of the annular space with the casing and the inner ring, can advantageously be reproduced. It is possible to avoid replacing the entire inner ring or a casing segment. It is thus possible for the repair procedure to be advantageously simplified, in that the repair time can be shortened and the material costs and replacement part costs can be reduced.

In the prior art, a damaged casing or inner ring without the wear protection coating according to the invention can be repaired for example by means of two different techniques. The first technique comprises what is referred to as smoothing out the damaged regions or points. This smoothing out often does not reproduce the geometric original state of the annular space. This can lead to increases in the gap at the guide vane tabs. Increases in the gap can have a negative influence on the efficiency and the surge limit of the turbomachine, for example when configured as a compressor. The second technique comprises applying a metallic coating with subsequent reworking, for example in order to keep to predefined geometric tolerances. The application of a metallic coating with subsequent reworking can lead to increased costs as a consequence of onerous repair and reworking. In comparison to the two prior art techniques, the wear protection arrangement, according to the invention, with separable wear protection coatings provides an advantageous simple, quick and cost-effective possibility for repairing by renewing the wear protection coating.

In some exemplary embodiments according to the invention, the wear protection coating is connected to the inner ring such that a guide vane or a vane tab (a radially inner or outer end of the vane) which in this embodiment has no protection coating cuts or digs into the wear protection coating at certain operating points. Such an operating point can for example provide a very high or a very low volume flow rate through the turbomachine, such that the adjustment angles of the guide vane are positioned in one or other end region of the adjustment range of the guide vane. It is equally possible, for example, for both the casing inner side and the outer guide vane tab to have a wear protection coating. Further combinations are also possible.

In some embodiments according to the invention, the wear protection coating is not a run-in cladding. A run-in cladding can be provided to carve out recesses to form a gap between the guide vane and the casing and/or the inner ring.

In some embodiments according to the invention, the wear protection coating is adhesively bonded, soldered, welded, thermally sprayed onto the base material and/or connected in a form-fitting manner to the base material.

In certain embodiments according to the invention, the wear protection coating is abradable or abrasive. The wear protection coating can comprise a material or a plurality of materials which are abradable or abrasive.

In the context of an abrasion procedure, a tool or a component can be moved back and forth on a further component, with application of a certain mechanical pressure, with material being removed from the further component. In some embodiments according to the invention, the guide vane (more specifically the guide vane tab) can rub against the wear protection coating and thus remove material from the wear protection coating.

In other words, the wear protection coating is abraded in the contact regions by the guide vane. This removal can be a chip-forming removal.

In certain exemplary embodiments according to the invention, an abradable wear protection coating has a porous metal matrix. A porous metal matrix can be termed a metal matrix with pores or with a pore structure. The pore structure can be open, closed or partially open and closed.

In some exemplary embodiments according to the invention, the metal matrix comprises at least aluminum, an aluminum-silicon alloy, nickel or a nickel-chromium-aluminum alloy.

In some exemplary embodiments according to the invention, the pore fraction of the porous metal matrix is between 3% and 35%. A metal matrix with a pore fraction of 35% can be termed open-pored in comparison with a metal matrix having a pore fraction of 3%. An open-pored metal matrix can present less resistance to abrasion than a less open-pored metal matrix.

In certain exemplary embodiments according to the invention, the wear protection coating is abrasive. In the context of an abrasion procedure, an abrasion means can work a second material in an abrasive manner. In that context, generally the second material is removed by the abrasion means.

In certain exemplary embodiments according to the invention, the thickness of the abradable wear protection coating is between 0.1 mm and 2 mm.

In certain exemplary embodiments according to the invention, an abrasive wear protection coating comprises a carbidic, nitridic and/or carbonitridic material. Carbides can be understood as a group of chemical compounds consisting of the element carbon C and a further element E. In general, a carbide can be written with the formula EₓC_{y}. General examples of carbides are titanium carbide and tungsten carbide. A nitridic material has, instead of carbon C in the carbidic material, the element nitrogen N. A carbonitridic material has both carbon C and nitrogen N.

In some exemplary embodiments according to the invention, the abrasive wear protection coating has a material composition of the form (M1)ₐ(M2)_{b}N_{c}C_{d}. N denotes nitrogen and C denotes carbon. The abbreviations M1 and M2 denote at least one of the metals aluminum, titanium, zirconium, chromium or tungsten. The stoichiometric factors a, b, c, d have one of the values zero, one, two, three or four. At least one of the factors a, b, c, d is greater than zero. If c and d are greater than zero, it is for example a carbonitridic material.

In some exemplary embodiments according to the invention, the abrasive wear protection coating has one or more layers, wherein multiple layers can have the same or different material compositions of the form (M1)ₐ(M2)_{b}N_{c}C_{d}. A single-layer wear protection coating can be termed a monolayer, a multi-layered wear protection coating can be termed a multilayer.

In certain exemplary embodiments according to the invention, the abrasive wear protection coating has at least one metal matrix with embedded particles. One or more of the metals of the metal matrix can comprise or have aluminum, titanium, zirconium, chromium or tungsten. The particles can have a material composition of the form (M1)ₐ(M2)_{b}N_{c}C_{d}, wherein N is nitrogen and C is carbon, and M1 and M2 comprises at least aluminum, titanium, zirconium, chromium or tungsten. The stoichiometric factors a, b, c, d have one of the values zero, one, two, three or four, wherein at least one of the factors a, b, c, d is greater than zero.

In some embodiments according to the invention, it is not possible, in the adjustment range of the guide vane, to move an abrasive wear protection coating on a radially outer guide vane tab against an abrasive wear protection coating in the casing section of the adjustment range.

In some embodiments according to the invention, it is not possible, in the adjustment range of the guide vane, to move an abrasive wear protection coating on a radially inner guide vane tab against an abrasive wear protection coating in the inner ring section of the adjustment range.

The following table summarizes certain embodiments according to the invention for preferred combinations of wear protection coatings which are connected to the guide vane, the casing and/or the inner ring.

Legend:

“++”—preferred combination

“+”—possible combination

“−−”—not a preferred combination

| | | guide vane | | |
|---|---|---|---|---|
| | | without wear | with wear | |
| | | protection | protection coating | |
| | | coating | abradable | abrasive |
| casing | abradable wear | ++ | + | ++ |
| and/or | protection | | | |
| inner ring | coating | | | |
| | abrasive wear | + | + | −− |
| | protection | | | |
| | coating | | | |

Purely exemplary examples for possible materials for the wear protection coatings, abradable or abrasive, and for the guide vanes are indicated below. The wear protection coatings and the guide vanes may be made entirely, partially or not at all from these materials. However, possible materials are not limited to these exemplary examples.

Purely exemplary materials for the adjustable guide vanes are:
titanium (Ti), e.g. Ti64, titanium alloys,
steel (e.g. with the alloying constituents X4NiCrTi2515 or X5NiCrTi2615),
nickel-chromium alloys.

Purely exemplary materials or configurations for abradable wear protection coatings are:
metal matrix with pores (as two-phase wear protection coating),
metal matrix with pores and a solid lubricant (as three-phase wear protection coating),
metal matrix (synonym: metallic matrix) having for example aluminum (Al), aluminum-silicon (AlSi), nickel (Ni), nickel-chromium-aluminum alloy and/or further materials,
pore fraction of the metal matrix with pores between 3% and 35%,
solid lubricant having for example graphite, boron nitride (BN), bentonite,
thickness of the abradable wear protection coatings between 0.1 mm and 2.0 mm,
epoxy resins,
aluminum/silicon (AlSi)/polyester.

Purely exemplary materials or configurations for abrasive wear protection coatings:
single-layer (monolayer) or multi-layered (multilayer) wear protection coatings (a wear protection coating can be termed a cladding),
multilayers can have homogeneous or inhomogeneous (different) material compositions,
monolayers or multilayers can have carbidic, nitridic and/or carbonitridic hard material phases,
carbidic, nitridic or carbonitridic hard material phases may have the following material composition: (M1)ₐ(M2)_{b}N_{c}C_{d}, with the following legend:
   N: nitrogen; C: carbon,
   M1, M2: metals from the group aluminum, titanium, zirconium, chromium, tungsten,
   a, b, c, d: stoichiometric factors which have the values zero, one, two, three or four, wherein at least one of the factors a, b, c, d is greater than zero;
exemplary example for a material composition of the form (M1)ₐ(M2)_{b}N_{c}C_{d} (without stoichiometric indication): titanium carbonitride (Ti(C,N))
monolayers or multilayers may be a homogeneous multi-phase system comprising:
   a ductile metal matrix having at least one metal from the group aluminum (Al), titanium (Ti), zirconium (Zr), cobalt (Co), nickel (Ni), iron (Fe), chromium (Cr); and
   embedded hard material particles, for example carbidic, nitridic or carbonitridic hard material particles having the material composition (M1)ₐ(M2)_{b}N_{c}C_{d}, (N: nitrogen; C: carbon; M1, M2: metals from the group aluminum, titanium, zirconium, chromium, tungsten; a, b, c, d:
stoichiometric factors having the values zero, one, two, three or four);
aluminum oxide Al₂O₃,
zirconium oxide.

In a purely exemplary manner, the table indicated above can have the following preferred material combinations:

Legend:

examples indicated: preferred combination

“−−”—not a preferred combination

| | | guide vane | | |
|---|---|---|---|---|
| | | without wear | with wear | |
| | | protection | protection coating | |
| | | coating | abradable | abrasive |
| casing | abradable | guide vane: | | protection |
| and/or | wear | Ti/Ti alloy/steel | | coating for the |
| inner | protection | protection | | guide vane: |
| ring | coating | coating for the | | monolayer or |
| | | casing and/or for | | multilayer with |
| | | the inner ring: | | embedded hard |
| | | metal matrix | | material particles |
| | | with pores, | | (M1)ₐ(M2)_{b}N_{c}C_{d}, |
| | | optionally with a | | protection |
| | | solid lubricant | | coating for the |
| | | | | casing and/or for |
| | | | | the inner ring: |
| | | | | metal matrix |
| | | | | with pores, |
| | | | | optionally with a |
| | | | | solid lubricant |
| | abrasive | | | −− |
| | wear | | | |
| | protection | | | |
| | coating | | | |

Some or all embodiments according to the invention can have one, several or all of the advantages mentioned above and/or below.

The wear protection arrangement according to the invention makes it advantageously possible to avoid direct contact between a coated or non-coated vane tab and the base material of the inner ring and/or of the casing. The base material of the inner ring and/or of the casing is that material onto which a wear protection coating can be applied. The wear protection arrangement according to the invention makes it possible to prevent damage to the base material of the inner ring and/or of the casing, and thus to ensure that only the wear protection coating (synonym: the cladding) needs to be repaired and/or renewed should the need arise. This has the advantage that repair costs downtimes and replacement part costs can be reduced.

The gaps between the guide vane on one hand and the casing and/or the inner ring on the other hand are commonly configured such that, in operation, there is no contact between the guide vane and the casing and/or the inner ring. The wear protection arrangement according to the invention, with the wear protection coating, now makes it possible to configure narrower gaps since contact with the wear protection arrangement does not lead to appreciable consequent damage and accordingly high costs (as described above). This leads to an advantageous increase in the efficiency of the turbomachine and to an increase in the surge limit.

According to the prior art, any contact and cutting of the guide vanes into the casing and/or into the inner ring is repaired by smoothing. A possible consequence of this is a permanent increase in the size of the gap at the vane tab. Renewing the wear protection coating according to the invention makes it possible to return to the original narrower gap. This can advantageously lead to an improvement in efficiency and improvement in the surge limit during an overhaul (maintenance) of the turbomachine, wherein the turbomachine can take the form of an aero engine or part of an aero engine.

### BRIEF DESCRIPTION OF THE DRAWINGS

The present invention is explained by way of example in the following, with reference to the appended respectively schematically simplified drawings in which identical reference signs denote identical or similar components, and in which:

FIG. 1 shows an adjustable guide vane in a turbomachine according to the prior art;

FIG. 2 shows a wear protection arrangement according to the invention with a wear protection coating connected to an inner ring;

FIG. 3 is a perspective representation of the wear protection arrangement according to the invention from FIG. 2;

FIG. 4 is a further perspective representation of the wear protection arrangement according to the invention from FIG. 2;

FIG. 5 shows a wear protection arrangement according to the invention with a wear protection coating connected to a casing;

FIG. 6 is a further view of the wear protection arrangement according to the invention from FIG. 5;

FIG. 7 is a perspective view of the wear protection arrangements according to the invention from FIGS. 2 to 6;

FIG. 8 shows a wear protection arrangement according to the invention with a wear protection coating on a radially outer end of the guide vane;

FIG. 9 is a perspective view of the wear protection arrangement according to the invention from FIG. 8;

FIG. 10 shows a wear protection arrangement according to the invention with a wear protection coating on a radially inner end of the guide vane; and

FIG. 11 is a detail view of the wear protection coating on the radially inner end of the guide vane.

### DETAILED DESCRIPTION OF EMBODIMENTS

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show details of the present invention in more detail than is necessary for the fundamental understanding of the present invention, the description in combination with the drawings making apparent to those of skill in the art how the several forms of the present invention may be embodied in practice.

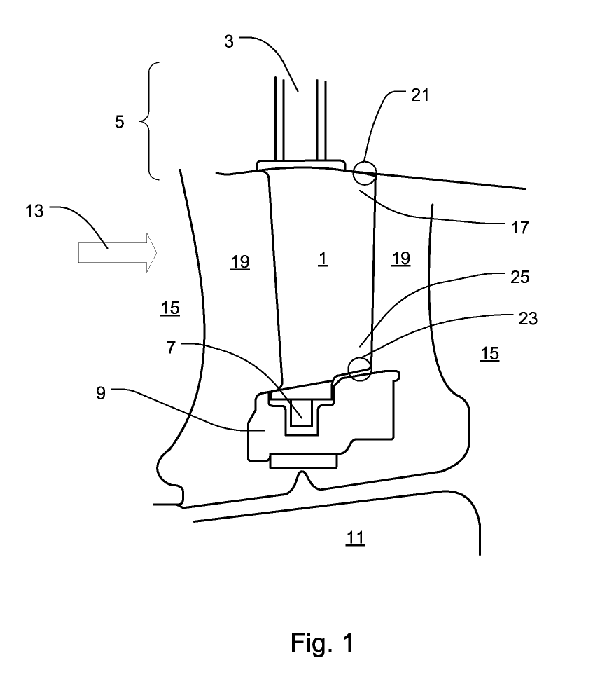

FIG. 1 shows an adjustable guide vane 1 in a turbomachine according to the prior art. The guide vane 1 is mounted rotatably with an outer peg 3 in a casing 5 and with an inner peg 7 in an inner ring 9 of the turbomachine. A rotor 11 is connected to rotor blades 15 arranged upstream and downstream (in the main flow direction 13).

At certain operating points of the turbomachine, adjusting or turning the guide vane 1 can cause contact between the guide vane 1 and the casing 5 and/or with the inner ring 9. Such contact can cause damage to the housing 5 and/or to the inner ring 9. Such damage can cause indentations for example with a sickle-shaped contour. The damage may make it necessary to repair or replace at least the damaged casing regions and/or the damaged inner ring 9. This can lead to downtime, high breakdown costs, maintenance costs and replacement part costs.

In FIG. 1, such damage in the region of the main throughflow duct 19, which in the following is termed flow duct 19, of the casing 5 can occur, caused by the radially outer vane tab 17. This region is represented in FIG. 1 as the casing region 21 between the outer vane tab 17 and the casing 5.

Similarly to the described damage in the casing region 21, contact between an inner vane tab 25 and the inner ring 9 can occur in an inner ring region 23 between the inner vane tab 25 and the inner ring 9. This damage to the inner ring 9 can also make it necessary to repair or replace the latter.

The damage can exhibit sickle-shaped indentations.

The arrangement according to the prior art in FIG. 1 is in particular an arrangement in high-pressure compressors of turbomachines. The described damage can however also occur in other regions of adjustable vanes in turbomachines, for example in the region of turbines, low-pressure compressors, fans or the like.

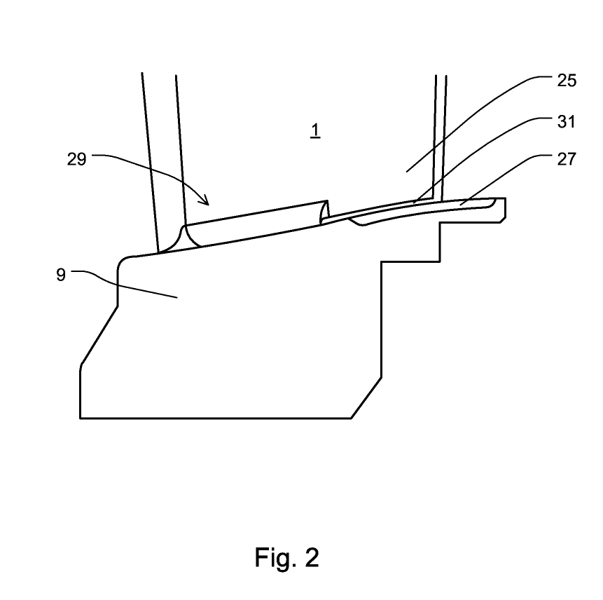

FIG. 2 shows a wear protection arrangement according to the invention with a wear protection coating 27 connected to the inner ring 9. The adjustable guide vane 1 is mounted rotatably in the inner ring 9 by means of a mounting 29. A gap 31 is represented between the radially inner end of the guide vane 1 (the inner vane tab 25) and the wear protection coating 27. This gap 31 is generally designed to be small or narrow, in order to minimize flow losses (what are referred to as gap losses). This gap minimization can result, at certain operating points of the turbomachine, when adjusting or turning the guide vane 1, in contact between the guide vane 1 and the wear protection coating 27. Contact is in particular caused or exacerbated by possible so-called ovalities (out-of-roundnesses) of the mounting or guiding of the guide vane 1 in the inner ring 9.

The ovalities may be caused by various factors. For example, thermal deformations during operation of the turbomachine or eccentricities of the inner mounting 29 and/or of the outer mounting (in particular eccentricities of the bushings or of the pegs 3, 7) can cause ovalities. Alternatively or in addition, pressure forces and/or thrust deformations or maneuvering deformations can lead to ovalities.

Furthermore, contact between the guide vane 1 and the wear protection coating 27 can occur as a consequence of wear. For example, contact can occur as a consequence of thermal loads and/or frequent turning of the adjustable guide vane 1. In further embodiments, the pegs 3, 7 can be guided in bushings, which are respectively connected to the casing and/or to the inner ring. These bushings can wear, in particular if the bushings are manufactured from an abrasion-optimized material that is softer than the casing material and/or than the inner ring material.

In the absence of the wear protection coating 27 according to the invention, it is possible, as shown in FIG. 1, for direct contact to occur between the inner guide vane tab 25 and the inner ring 9. This could lead to damage to the inner ring 9 to the extent that repair and replacement of entire components is necessary. By contrast, the wear protection coating 27 according to the invention can be configured such that only the wear protection coating 27 itself (that is to say not the guide vane tab 25) is abraded, worn away or removed. Removal of this type can take the form of a sickle-shaped indentation or depression (on account of the rotation of the vane tab 25 in the wear protection coating 27).

Depending on the duration of operation of the turbomachine and on the state of the wear protection coating 27 (for example in the case of an enlarged gap 31 between the vane tab 25 and the wear protection coating 27), the wear protection coating 27 can be replaced or exchanged without having to replace larger components or carry out repairs on the vane 1 or the inner ring 9. It is thus possible to reduce repair costs. Furthermore, downtime, high breakdown costs, maintenance costs and replacement part costs can be reduced.

The pairing of materials between the inner vane tab 25 and the wear protection coating 27 should be chosen such that the vane tab 25 can abrade or wear down the wear protection coating 27. In particular, the material of the vane tab 25 should be harder than that of the wear protection coating 27.

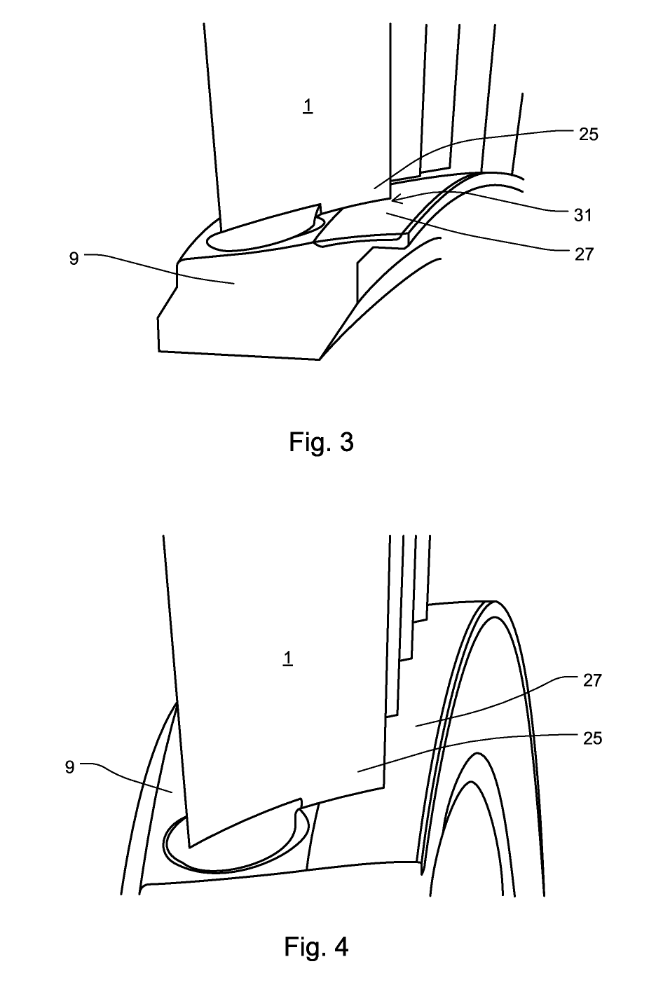

FIG. 3 and FIG. 4 are perspective representations of the wear protection arrangement according to the invention from FIG. 2. Multiple adjustable guide vanes 1 are arranged on the circumference of the inner ring 9. Each guide vane 1 can, at certain operating points of the turbomachine, when adjusting or turning the respective guide vane 1, come into contact with the wear protection coating 27. The wear protection coatings 27 can be removed by abrasion or wearing away by the inner vane tabs 25.

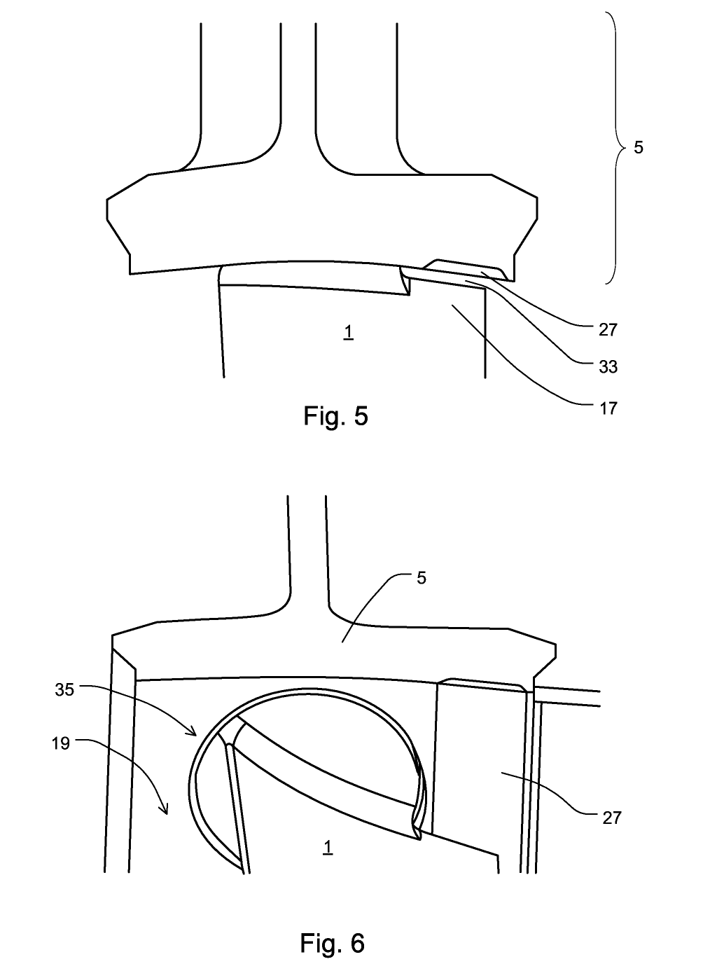

FIG. 5 shows a wear protection arrangement according to the invention with a wear protection coating 27 connected to the casing 5. The outer vane tab 17 can abrade, wear away or remove regions of the wear protection coating 27. The discussion relating to a gap 33 and the material pairings is applicable by analogy with the descriptions of FIGS. 2 to 4.

FIG. 6 shows a further view of the wear protection arrangement according to the invention from FIG. 5. The wear protection coating 27 is represented both in the casing section and also partially over the circumference on the inner side of the casing 5 in the flow duct 19. Also shown is the mounting 35 of the adjustable guide vane 1 in the casing 5.

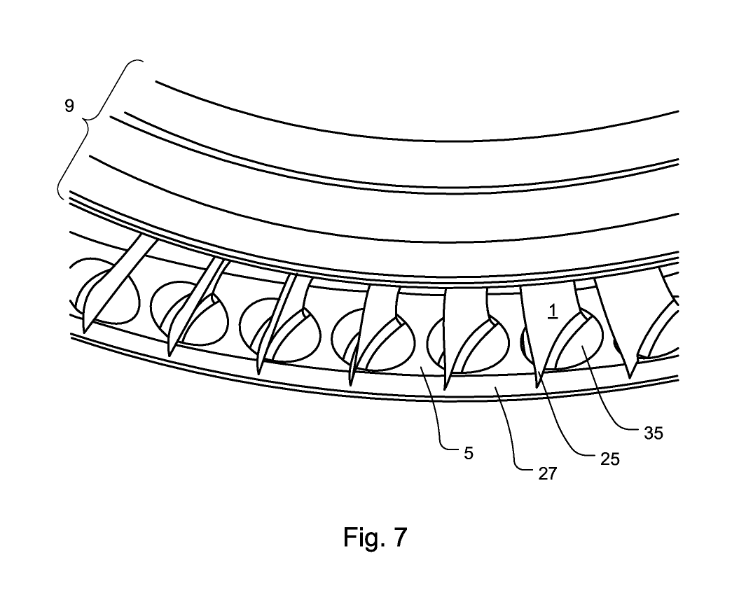

FIG. 7 is a perspective view of the wear protection arrangements according to the invention from FIGS. 2 to 6. The adjustable guide vanes 1 are arranged between the inner ring 9 and the casing 5. The mounting 35 of the guide vane 1 in the casing 5 is shown in FIG. 7, the mounting 29 of the guide vane 1 in the inner ring 9 is hidden. The inner vane tabs 25 of the guide vanes 1 are arranged close to the wear protection coating 27 and can, at certain operating points, come into contact with the wear protection coating 27.

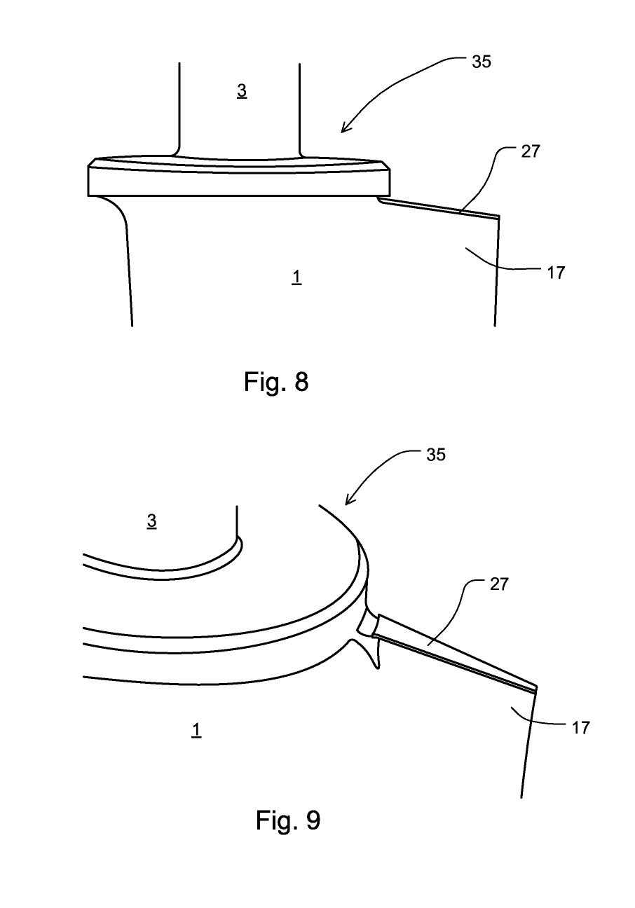

FIG. 8 shows a wear protection arrangement according to the invention with a wear protection coating 27 on a radially outer end of the guide vane 1. The wear protection coating 27 is directly connected to the outer vane tab 17. The guide vane 1 is mounted in the casing 5 (not shown in FIG. 8) by means of the mounting 35 and the outer peg 3.

FIG. 9 is a perspective view of the wear protection arrangement according to the invention from FIG. 8.

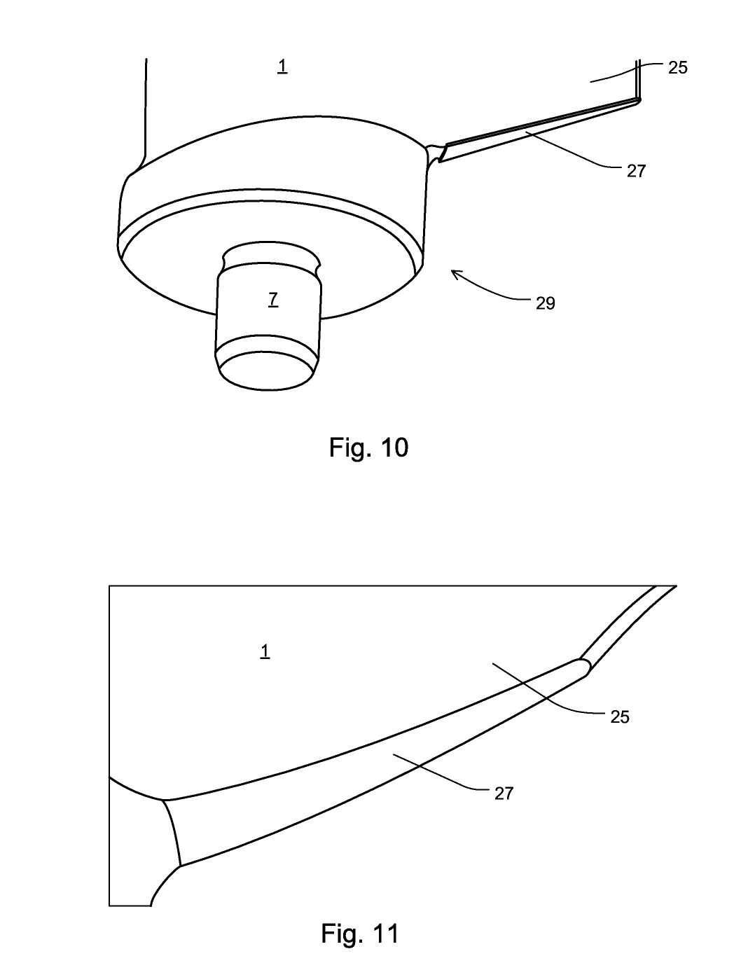

FIG. 10 shows a wear protection arrangement according to the invention with a wear protection coating 27 on a radially inner end of the guide vane 1. Similarly to FIG. 8, the wear protection coating 27 is directly connected to the inner vane tab 25. The guide vane 1 is mounted in the inner ring 9 (not shown in FIG. 10) by means of the mounting 29 and the inner peg 7.

FIG. 11 is a detailed view from FIG. 10 with the wear protection coating 27 on the radially inner end of the guide vane 1.

### LIST OF REFERENCE SIGNS

1 adjustable guide vane
3 outer peg
5 casing
7 inner peg
9 inner ring
11 rotor
13 flow direction
15 rotor blade
17 outer vane tab
19 flow duct; main throughflow duct
21 casing region between outer vane tab and casing
23 inner ring region
25 inner vane tab
27 wear protection coating
29 mounting for the adjustable guide vane in the inner ring
31 gap between the inner vane tab and the wear protection coating
33 gap between the outer vane tab and the wear protection coating
35 mounting for the adjustable guide vane in the casing

1.-14. (canceled)

15. A wear protection arrangement for a turbomachine, wherein the arrangement comprises
at least one adjustable guide vane,
a casing in which the at least one guide vane is arranged in an adjustable manner,
an inner ring made from a metallic material, in or on which ring the at least one guide vane is arranged in an adjustable manner,
a first gap between an inner guide vane tab and the inner ring and a second gap between an outer guide vane tab and the casing,
one or more wear protection coatings connected to the inner ring and/or to the inner guide vane tab and forming the first gap, at least in certain regions,
and/or one or more wear protection coatings connected to the casing and/or to the outer guide vane tab and forming the second gap, at least in certain regions.

16. The wear protection arrangement of claim 15, wherein the one or more wear protection coatings are abradable or abrasive.

17. The wear protection arrangement of claim 16, wherein the one or more wear protection coatings are abradable.

18. The wear protection arrangement of claim 16, wherein the one or more wear protection coatings are abrasive.

19. The wear protection arrangement of claim 17, wherein the one or more wear protection coatings are or comprise a porous metal matrix.

20. The wear protection arrangement of claim 19, wherein the metal matrix comprises at least one of aluminum, an aluminum-silicon alloy, nickel, a nickel-chromium-aluminum alloy.

21. The wear protection arrangement of claim 19, wherein a pore fraction of the porous metal matrix is from 3% to 35%.

22. The wear protection arrangement of claim 20, wherein a pore fraction of the porous metal matrix is from 3% to 35%.

23. The wear protection arrangement of claim 17, wherein the wear protection coating comprises a porous metal matrix and a solid lubricant.

24. The wear protection arrangement of claim 23, wherein the metal matrix comprises at least one of aluminum, an aluminum-silicon alloy, nickel, a nickel-chromium-aluminum alloy.

25. The wear protection arrangement of claim 23, wherein a pore fraction of the porous metal matrix is from 3% to 35%.

26. The wear protection arrangement of claim 24, wherein a pore fraction of the porous metal matrix is from 3% to 35%.

27. The wear protection arrangement of claim 17, wherein the wear protection coating has a thickness of from 0.1 mm to 2 mm.

28. The wear protection arrangement of claim 18, wherein the wear protection coating comprises a carbidic, nitridic and/or carbonitridic material.

29. The wear protection arrangement of claim 18, wherein the wear protection coating has a composition represented by (M1)ₐ(M2)_{b}N_{c}C_{d}, wherein N is nitrogen and C is carbon, M1 and M2 comprise at least one of aluminum, titanium, zirconium, chromium, tungsten, and the stoichiometric factors a, b, c, d are each zero, one, two, three or four, at least one of a, b, c, d being greater than zero.

30. The wear protection arrangement of claim 29, wherein the one or more wear protection coatings comprise one or more layers, multiple layers having the same or different compositions (M1)ₐ(M2)_{b}N_{c}C_{d}.

31. The wear protection arrangement of claim 29, wherein the one or more wear protection coatings comprise at least one metal matrix with embedded particles, which particles having a composition represented by (M1)ₐ(M2)_{b}N_{c}C_{d}, wherein N is nitrogen and C is carbon, M1 and M2 comprise at least one or aluminum, titanium, zirconium, chromium, tungsten, and the stoichiometric factors a, b, c, d are each zero, one, two, three or four, at least one of a, b, c, d being greater than zero.

32. A method for applying one or more abradable wear protection coatings to the inner ring and/or the casing of the wear protection arrangement of claim 17, wherein the method comprises applying the one or more wear protection coatings by thermal spraying.

33. A method for applying one or more abrasive wear protection coatings to the inner guide vane tab and/or to the outer guide vane tab of the wear protection arrangement of claim 18, wherein the method comprises applying the one or more wear protection coatings by thermal spraying, physical vapor deposition (PVD) or chemical vapor deposition (CVD).

34. A compressor for a turbomachine, wherein the compressor comprises at least one wear protection arrangement according to claim 15.
